(19) United States
(12) Patent Application Publication
(10) Pub. No.: US 2007/0096812 A1
(43) Pub. Date: May 3, 2007

(54) SWITCHING AMPLIFIER WITH OUTPUT FILTER FEEDBACK

(76) Inventor: Wai L. Lee, Austin, TX (US)

Correspondence Address: PATENT-TRADEMARK-COPYRIGHT. US, 2200 S. FORT APACHE ROAD #1213, LAS VEGAS, NV, 89117, US

(21) Appl. No.: 11/309,360

(22) Filed: Jul. 31, 2006

Related U.S. Application Data
(63) Continuation-in-part of application No. 11/308,122, filed on Mar. 7, 2006.
(63) Continuation-in-part of application No. 11/307,988, filed on Mar. 2, 2006.
(63) Continuation-in-part of application No. 10/811,453, filed on Mar. 26, 2004, now Pat. No. 7,038,535.

(51) Int. Cl. H03F 3/217

(52) U.S. Cl. 330/251

(57) ABSTRACT

An improved PWM amplifier is disclosed that uses multiple integrators in the loop filter to provide high loop gain across the frequency band-of-interest. The frequency characteristics of the loop filter is optimized to distribute large loop gains across the entire selected frequency band to provide large suppression of noise and distortions generated in the modulation and output stages. In another aspect of the invention, a method of recovering from overload conditions in high-order PWM amplifiers is disclosed that quickly and automatically restores stable closed loop operation.

### CROSS REFERENCE TO RELATED APPLICATION

This continuation-in-part application claims the benefit of co-pending U.S. patent application Ser. No. 11/307988, filed Mar. 2, 2006 and U.S. patent application Ser. No. 11/308,122, filed Mar. 7, 2006 which are continuation patent applications of U.S. patent application Ser. No. 10/811,453, filed Mar. 26, 2004 and Provisional Application No. 60/458,889, filed Mar. 29, 2003, now U.S. Pat. No. 7,038,535 which are hereby incorporated.

### BACKGROUND OF THE INVENTION

1. Field of the Invention

The present invention relates generally to amplifiers. More specifically, the present invention relates to systems and methods for efficient amplification of signals using Class D or PWM (pulse width modulation) digital amplifiers.

2. Description of the Related Art

Amplifier designers and manufacturers continue to be pressured to reduce costs, improve efficiency, decrease size & power dissipation, improve output signal quality, reduce electromagnetic and radio frequency emissions, and increase tolerance of noise, distortion, & interference. Although there does not appear to be one complete solution, various signal amplification systems and methods have been proposed to address the various problems.

One technique that has been proposed to increase efficiency over traditional linear amplification is pulse-width modulation (PWM). Despite their inherent power efficiency advantages, there are many difficulties that make it difficult for PWM (or Class D) digital amplifiers to achieve high fidelity performance that can compete effectively with conventional linear (or Class AB) analog amplifiers.

With PWM amplifiers, power supply noise, jitter, circuit noise, and non-linearities in the modulating carrier waveform may be modulated onto the PWM output. Furthermore, to better compete with traditional solutions, it is desirable to reduce the sensitivity of PWM amplifiers to these noise and error sources in order to relax overall system requirements and reduce system costs. Sophisticated techniques have been proposed to attack each of these noise components with limited success. In many instances, the proposed solution increases size, complexity and cost.

PWM amplifiers often require an output filter to suppress undesirable high-frequency components. These output filters are constructed with large passive components. These components have non-linear behaviors at high current and voltage levels that can degrade the high fidelity performance of the system. Consequently, large or expensive filter components are used to reduce the distortion introduced by the output filter. Furthermore, the frequency response of the output filter varies with load conditions. In order to minimize the frequency response variations, the output filters are designed with relatively high low-pass frequencies that reduce its effectiveness in suppressing the undesirable high-frequency components.

Therefore, there is a desire to provide rejection of noise and distortion originating from the output filter components, so that smaller and inexpensive filter components can be used. There is also a desire to minimize frequency response deviations due to load variations.

### SUMMARY OF THE INVENTION

In accordance with one aspect of the present invention, a pulse-width modulated signal amplifier and amplification method amplifies an incoming digital signal and produces an output digital signal using a pulse-width amplification technique that includes a feedback loop filter. In accordance with another aspect of the invention, the feedback loop filter uses an integrator filter with a filter order higher than one. In accordance with another aspect of the invention, the feedback loop filter includes a limiter to control overload. In accordance with another aspect of the invention, the feedback loop filter includes a technique that is inherently stable as it recovers from overload.

### BRIEF DESCRIPTION OF THE DRAWINGS

FIG. 1 is a block diagram of a prior art embodiment of a PWM amplifier,

FIG. 2 is an embodiment a PWM amplifier in accordance with the invention,

FIG. 3 shows an embodiment of the high-pass filter (HPF) in accordance with the invention,

FIG. 4 shows the frequency response of a) the low-pass output filter, b) the high-pass filter (HPF), and c) the sum of the low-pass and high-pass filters at FB,

FIG. 5 shows the rejection of distortion components originating from the output filter,

FIG. 6 shows a) the prior art frequency response of the output filter when the load impedance deviates substantially from nominal, and b) the frequency response of the output filter in accordance with the invention with the same deviation in load impedance,

FIGS. 7A & 7B shows an embodiment of the invention with a 3^{rd}-order loop filter and one implementation of the high-pass filter (HPF) in accordance with the invention,

FIG. 8 shows the frequency response of a (a) 1^{st}-order, (b) 3^{rd}-order, and (c) 5^{th}-order loop filter in accordance with the invention,

FIG. 9 shows an active filter implementation of the high-pass filter in accordance with the invention,

FIG. 10 shows a fully differential PWM amplifier in accordance with the invention,

FIG. 11 shows an embodiment of the invention where the low-pass filter and the high-pass filter are of different order, and

FIG. 12 shows an embodiment of the invention where the feedback is from after the speaker using a microphone transducer.

### DESCRIPTION OF THE PREFERRED EMBODIMENTS

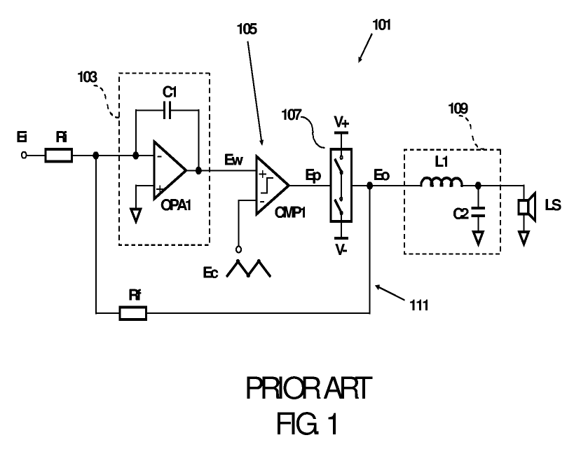

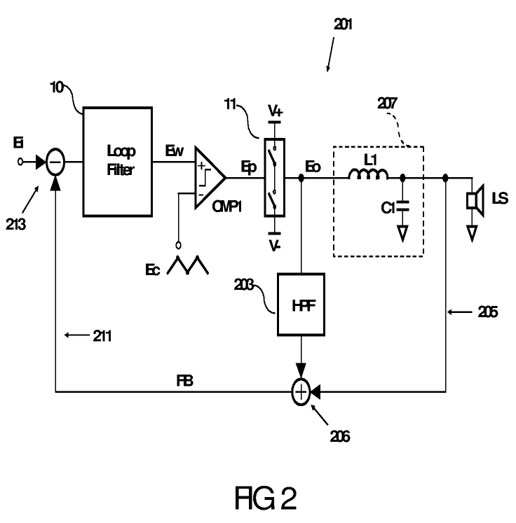

Referring to FIG. 1, a diagram of prior art pulse-width modulation (PWM) amplifier 101 with first order loop filter 103 is shown as disclosed in U.S. Pat. No. 4,504,793. In prior art amplifier 101, pulse-width modulation is accomplished by inputting an input voltage signal Ei through serially connected integrator circuit 103 (also referred to as a loop filter) and comparator CMP1 (105). The integrator circuit 103 integrates the difference between the input signal Ei and a feedback signal representative of Eo. Comparator 105 compares triangular wave voltage signal Ew with a pre-determined triangular carrier voltage signal Ec to produce a stream of voltage signal pulses Ep with the same frequency as the carrier signal Ec and pulse-widths that are proportional to |Ew|, where ‘| |’ is defined as the magnitude. Pulsed signal stream Ep drives the switching output stage 107, such that when a pulse of stream EP is high (or has a positive voltage) the switches are closed for the width of the pulse and the corresponding pulse of output voltage stream Eo is driven to a voltage of 2V for the length of the pulse width of the corresponding pulse of pulsed stream Ep. Output voltage stream Ep is passed through low pass filter 109 to reduce transients and then drive speaker LS. The output of a PWM amplifier is a pulse stream with the signal content in the low-frequency audio band and images at integral multiples of the carrier frequency (fs).

Integrating filter 103 includes operational amplifier OPA1 having its positive input terminal connected to ground and its negative input terminal connected to resistors Ri and Rf and capacitor Cl which are used to integrate or amplify the time-averaged errors between the input signal Ei and output signal Eo. Switching output stage 107 comprises a set of power switches that operate in the fully ‘ON’ or fully ‘OFF’ states so that minimal power loss occurs and very high efficiency can be achieved with PWM amplifier 101. Passive low-pass filter 109 comprising inductor L1 and capacitor C2 is used to remove undesirable noise and recover desired signal content from output signal Eo. The filtered output signal is then delivered to speaker LS.

Integrating filter 103 provides high gain at low frequencies so that in closed loop 111, noise and distortions introduced by the PWM modulation process through comparator 105 and switching output stage 107 (comprising power switches), will be rejected by the gain of the integrating filter. However, it may be noted, output filter 109 is not in closed loop 111. Therefore, noise, distortions and other errors introduced by the components in output filter 109 are not rejected by the gain of integrating filter 103. At high power levels, the reactive components used in output filter 109 can introduce a substantial amount of distortions. For example, the magnetic material used in power inductors can approach saturation with high magnetic field densities. Therefore, one has to use large magnetic cores to keep the magnetic field densities well below the saturation point of the magnetic material. The need for large magnetic cores increases the cost and physical size of the system.

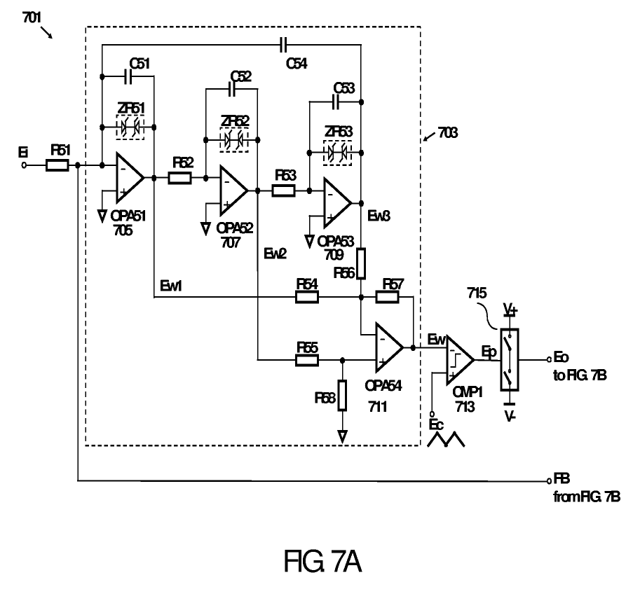

Furthermore, the impedance of the load LS can affect the frequency response of the loop filter. In applications where the load is not fixed or known, one generally designs for the nominal load and endeavors to design such that the frequency response is sufficiently flat within specifications over the range of anticipated load conditions. For example, FIG. 6, plot (a) shows that under load conditions, the frequency response of prior art amplifier 101 can droop by as much as 1.4 dB at 20 kHz. One can reduce the amount of deviation from a flat frequency response if the low-pass filter corner is increased. However, increasing the low-pass filter corner reduces the effectiveness of the output filter in removing the PWM carrier and high frequency images at the output. Allowing more high frequency image components may cause EMI (electro-magnetic interference) problems or force one to use a higher order low-pass filter which increases cost and board space.

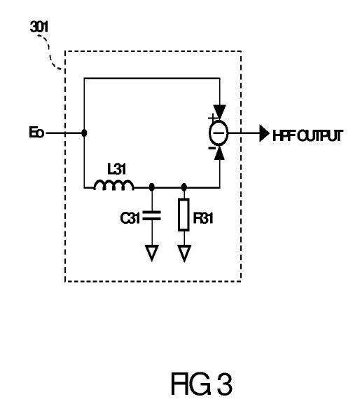

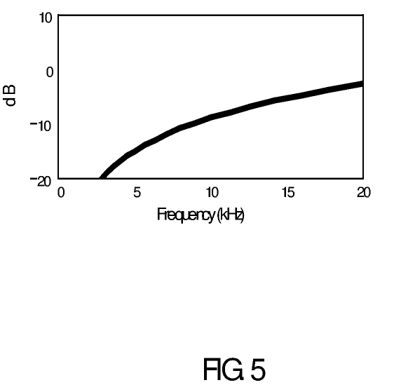

Referring to FIG. 2, a diagram of an embodiment of PWM amplifier 201 is shown that contains high-pass filter HPF 203 and feedback loop branch 205 which extends directly from the output of low-pass filter 207 to high-pass filter 203. The output of high-pass filter HPF 203 is summed with the feedback from the output of low-pass filter 207 using summer 206 to form the feedback signal FB delivered along feedback loop branch 211 and to subtractor 213. The low-frequency inband spectral components of the feedback signal FB is substantially from the low-pass filter output, and the high-frequency spectral components of the feedback signal FB is substantially from Eo. The frequency responses of low-pass filter 207 and high-pass filter HPF 203 are further illustrated in FIG. 4. In FIG. 4, plot (a) is the frequency response of low-pass filter 207. In this example, low-pass filter 207 has a −3 dB low-pass filter corner frequency of 40 kHz. The frequency response of high-pass filter HPF 203 is shown as plot (b). HPF 20 is designed so that when the HPF output and the low-pass filter outputs are summed, an all-pass frequency response is produced as shown in plot (c). In other words, high-pass filter HPF 203 is designed to provide the high frequency signal components that are removed by low-pass filter 207 so that when summed, a unity response is formed as feedback signal FB.

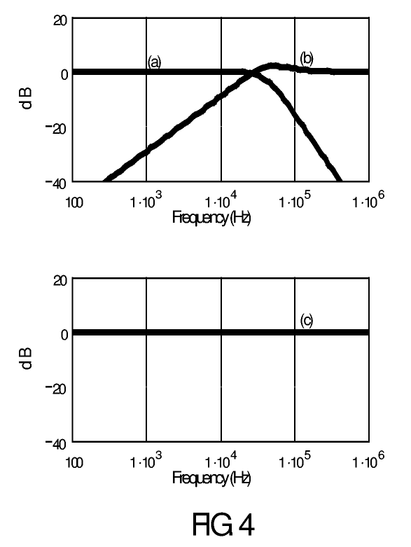

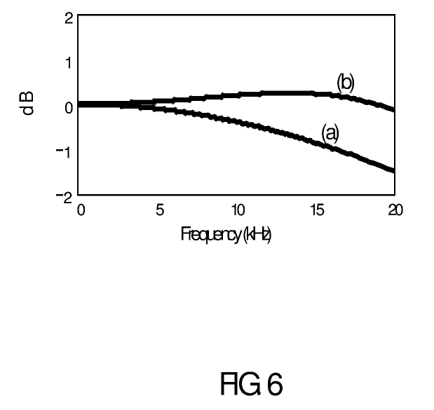

FIG. 3 shows an implementation of high-pass filter 301 (HPF 203 in FIG. 2). L32, C31, and R31 reproduce the frequency response of the low-pass filter 207 and the HPF output is formed as the difference between the input Eo and the replicated low-pass filter output. It may be appreciated that L, C, & R when associated with a component refer generally to inductors, capacitors, and resistors. It may further be appreciated that while the simple diagrams may show only one respective such component, combinations of such components may also be utilized such as with series or parallel coupled components. Additionally, it may be appreciated that while the filter shown is a first order filter, it may easily be designed as a second or higher order filter. Depending on the order or type of filter implemented as high-pass filter 301, low-pass filter 207 (as shown in FIG. 2 by example) should have a corresponding order or type to achieve the desired effect as the example combined low-pass (FIG. 4, plot (a)) and high-pass (FIG. 4, plot (b)) filter response shown in FIG. 4, plot (c). It can be appreciated that when the high-pass filter output is summed with the low-pass filter output as shown by example in FIG. 2, FB is ideally equivalent to Eo. But in the presences of in-band noise, distortion, and other errors at the output of the low-pass filter (eg low-pass filter 207 in FIG. 2), the in-band spectra components of the low-pass filter output are fed back and corrected by the gain of the loop filter. For example, FIG. 5 shows the amount of rejection of low-pass filter noise and distortion components in one embodiment. At 10 kHz, the multiple feedback arrangement in accordance with the invention provides 9 dB of rejection and at 5 kHz, 15 dB of rejection of low-pass filter noise and distortions are provided.

As previously stated, the impedance of the load can affect the frequency response of the low-pass filter. Ideally, the frequency response of the low-pass filter is flat over the low-frequency band-of-interest. In FIG. 6, plot (a) illustrates what happens to the frequency response when the load impedance is substantially different than the ideal impedance. It shows that the frequency response may droop by as much as 1.5 dB at the 20 kHz pass-band edge. In accordance with an embodiment of the invention, the errors of the pass-band frequency response of the low-pass filter due to the variations in the load impedance are fed back through FB and corrected by the gain of the loop filter 10 shown in FIG. 2. Consequently, the error in pass-band flatness is reduced to less than 0.25 dB as shown in FIG. 6, plot (b) and corresponding to a 6× improvement.

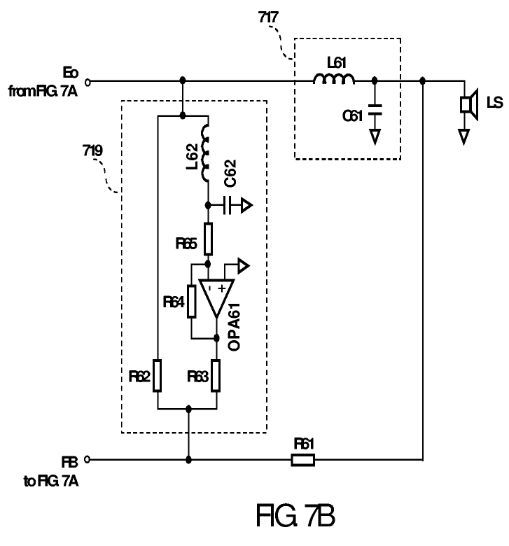

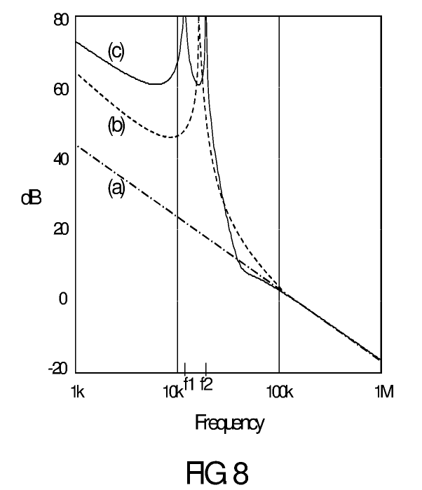

Referring to FIGS. 7A and 7B, a diagram of PWM amplifier 701 with 3^{rd} order loop filter 703 is shown as an example embodiment. 3^{rd} order loop filter 703 represents an example loop filter (e.g. loop filter 10 of FIG. 2) circuit design comprising a series of three integrators 705, 707, 709 that produces the loop filter response shown in curve (b) of FIG. 8. Integrators 705, 707, 709 are implemented as active RC integrators with respective operational amplifiers OPA51, OPA52, and OPA53, input resistors R51, R52, and R53, integrating capacitors C51, C52, and C53, and zener diodes ZR51, ZR52, and ZR53. C54 feeds back a small amount of signal from the OPA53 output to the input of OPA52 after being effectively inverted by OPA51 in order to feed back signal in the correct polarity without using an additional inverting amplifier.

From loop filter 703, output signal Ew2 is passed through a voltage divider comprised of resistors R55, R58 and to the positive input of opamp 711; output signal Ew3 is passed through a voltage divider comprised of resistors R56, R57 and to the negative input of opamp 711. Output signal Ew1 is passed through resistors R54, R57 and combined (such as additively) with the output signal from opamp 711 to develop loop output signal Ew. Loop output signal Ew and carrier signal Ec are input to comparator 713 to develop pulse width modulated signal Ep. Pulse width modulated signal Ep is delivered to switch 715 to control the operation and develop amplifier output signal Eo. Output signal Eo is delivered across low-pass filter 717 and high-pass filter 719. A portion of the low-pass filter response is passed across resistor R61, combined with the high-pass filter response, and fed back to the negative input node of opamp 705 together with the portion of input signal Ei which is passed through resistor R51 to the negative input node of opamp 705. The high-pass and low-pass filter responses may be combined as with a summer (shown in FIG. 2). The feedback signal FB may be substracted from the portion of input signal Ei transferred across resistor R51 as with a subtractor (shown in FIG. 2).

In one family of PWM amplifiers, carrier signal Ec may be selected as a 2V peak-to-peak triangular wave with a frequency preferably selected in the range of 300-500 kHz. When implemented with a 500 kHz carrier signal, the component values of PWM amplifier 701 are as follows:

| | | |
|---|---|---|
| R52 | 11 | k |
| R53 | 22 | k |
| R54 | 5.1 | k |
| R55 | 27 | k |
| R56 | 20 | k |
| R57 | 10 | k |
| R58 | 10 | k |
| R59 | 24 | k |
| C51 | 1000 | pf |
| C52 | 100 | pf |
| C53 | 100 | pf |
| C54 | 27 | pf |
| V+ | +12 | v |
| V− | −12 | v |

In this embodiment, ZR51, ZR52, and ZR53 are each implemented with a pair of back-to-back connected zener diodes with a breakdown voltage of 5.1V. to provide overload handling that simply clips or saturates and comes back into linear operation immediately when the overload condition is no longer present. The overload handling is accomplished in PWM amplifier 701 by using voltage clamps ZR51, ZR52, and ZR53 to limit the integrator state to within plus or minus of the clamp voltage (±5.7V), and by designing the loop filter output summer (OPA54, R54, R55, R56, R57, and R58) to allow sufficient gain for the first integrator, OPA51, to maintain stable closed loop operation even when the two subsequent integrators are still saturated. The voltage clamps are placed across the integrator capacitor; for example ZR52 is placed across C52 to limit the integrator output Ew2 to within plus or minus the clamp voltage. The clamp voltage is set sufficiently larger than the maximum expected signal during normal operation so that the voltage clamps do not interfere with normal signal processing except in the event of an overload situation. In an overload event, the integrator may be saturated and its output Ew2 may be clamped, for example at ±5.7V. As long as the overload condition exists, Ew1 is negative and Ew2 remains clamped at ±5.7V. Once the overload condition is removed and Ew1 crosses zero and turns positive, Ew2 integrates down from ±5.7V and the integration function is restored immediately. It is important for the integrators to avoid any delays in the transition from saturation to linear operation because delays will constitute additional dynamic mechanisms that can prevent the system from coming back into stable closed loop operation.

Referring to FIGS. 7A and 7B, a block diagram of PWM amplifier 701 with a 3^{rd} order loop filter 703 is shown where the feeding back output signal Eo to the negative input node of the first integrator of the loop filter, output signal Eo is principally passed through the low-pass filter 717 producing a signal that is principally delivered to speaker LS while a small portion of the signal is fed back over resistor R61 to a feedback node that is connected to the negative input node of the first loop integrator. A small portion of output signal Eo is passed through high pass filter 719 and resistor R62 to the feedback node and combined (such as additively) with the signal passing through resistor R63 to produce feedback signal FB. Feedback signal FB is fed back to the negative input node of the first loop integrator where it is combined (such as by differencing) with input signal Ei as modified by passing through resistor R51.

The loop filter frequency response of the example embodiment as illustrated in FIG. 7A and FIG. 7B is shown as plot (b) in FIG. 8. Also shown are frequency responses of other embodiments: a single integrator loop filter, plot (a); and a 5^{th}-order loop filter, plot (c). As the order of the loop filter increases, more loop gain can be applied to reduce the various noise and distortion components.

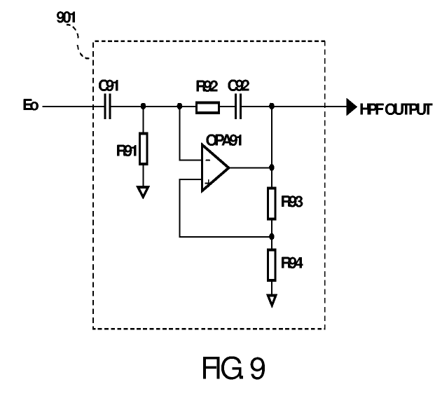

FIG. 9 shows an alternative embodiment of high-pass filter HPF 901 (such as in FIG. 2) using an active filter configuration. In integrated circuits (IC) implementations of the invention, it may be advantages to use an active filter configuration where the opamp OPA91 and much of the passive components can be easily integrated.

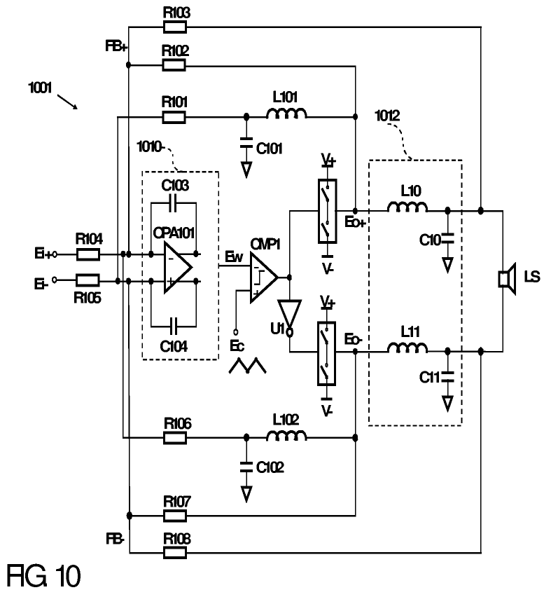

FIG. 10 shows an embodiment of a PWM amplifier 1001 where a fully differential loop filter implementation is used and a fully differential output that is also known in the field as BTL (bridge-tied load) output configuration. In the embodiment illustrated in FIG. 10, the fully differential configuration can be exploited to minimize active circuitry and simplify the high-pass filter HPF implementation. In this example, the Eo+ signal amplifier path includes high pass filter circuitry comprised of L101, C101 and R101 develops the corresponding response to combine with the low-pass frequency response of low pass filter 1012 comprising L10 and C10 and achieve the desired affects referred to previously. Note that the Eo-signal amplifier path has corresponding structure.

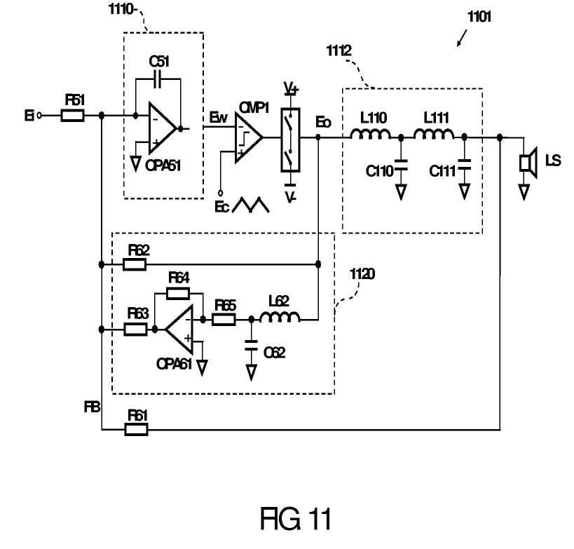

Referring to FIG. 11, an embodiment of PWM amplifier 1101 is shown where the order of the low-pass filter 1112 is different than that of the high-pass filter 1120. Although the higher-order low-pass filter, 4^{th}-order in this illustrative example, rolls off more sharply at high frequencies, it can be appreciated that the high-frequency response (above the filter corner frequencies of both filters) when the low-pass filter 1112 and the high-pass filter 1120 outputs are combined is essentially flat and therefore provides the necessary and sufficient signal components at FB to stabilize the loop.

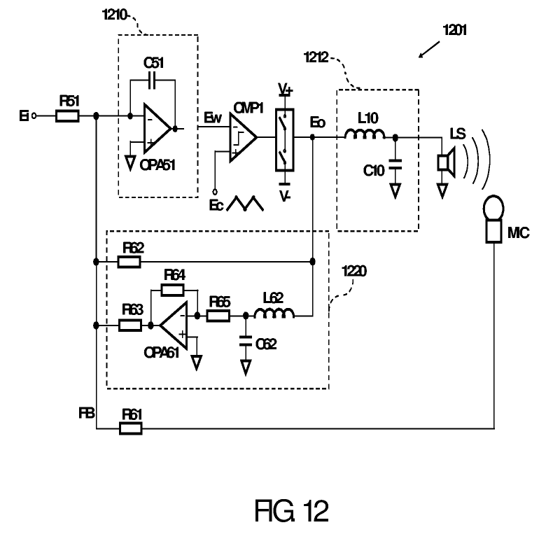

By way of an illustrative example, FIG. 12 shows an embodiment of PWM amplifier 1201 which taps the feedback signal from after the speaker through a microphone transducer MIC instead of after the low-pass filter. Since the low-pass filter 1212 already removes high-frequency spectral content of the signal going to the speaker LS, the signal pick up by the microphone transducer MIC can be made closely resembling the signal at the output of the low-pass filter by keeping the acoustic delay sufficiently small. The advantage of closing the loop after the speaker is that the distortion generated by the speaker and imperfections in the speaker's frequency response are inside the loop and therefore rejected by the loop gain. Therefore, the speaker's performance is effectively improved which is advantageous especially in low frequency signal applications where it is relatively easy to kept the acoustic delay small relative to the period of the signal, for example, in the woofer and subwoofer audio speaker applications.

It can be appreciated to those skilled in the art that any number of combinations of single-ended and differential circuit configurations can be adapted in accordance with the invention. For example, a BTL output configuration can be used in conjunction with a single-ended loop filter circuit configuration. Although the illustrated embodiments in this disclosure had shown a single-stage LC output filter, those skilled in the art will appreciate that higher-order, multi-stage LC output filters can be employed in place of the single-stage LC output filter. Furthermore, the HPF frequency response does not need to exactly complement the low-pass filter frequency response so that their sum is exactly equal to a flat unity response. Any number of well known filter approximation techniques and filter structures can be used in the design of the HPF so that a sufficiently approximated flat response is obtained in the sum of the HPF and low-pass filter outputs. Neither does the HPF corner frequency have to exactly match the corner frequency of the low-pass filter. A mismatch in the HPF and low-pass filter corner frequencies results in what is known in the field as a doublet that is largely inconsequential as long as the mismatch does not get excessively large.

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. For instance, specific component values and voltage supply values are for the sake of illustration and explanation. Various embodiments of the invention may utilize values that are different from what is specified herein. Additionally, the terms used in the following claims should not be construed to limit the invention to the specific embodiments disclosed in the specification and the claims. Also, while the representative range of carrier frequencies are presented by example for audio applications. Other ranges of frequencies may be more desirable for industrial applications such as sensors or measuring instrumentation depending on the types of signal measurements or instrument environments. For example with EEG or EKG equipment where the monitored signal may be very low frequencies, a much lower carrier frequency may be desirable. In other applications, such as radio telescope or seismic image amplification, very high carrier frequencies may be more desirable. Additionally, for different input and carrier frequencies, the herein described circuit blocks may be required to be modified in order to properly perform the described functions. For instance, at very high frequencies, opamps, resistors, capacitors, and inductors perform differently, and the respective blocks would require corresponding modifications in order for given blocks to perform the required functions as described herein.

What is claimed is:

1. A switching amplifier comprising:
a power switching stage for receiving a signal and generating a switched signal; and
a filter stage for receiving the switched signal;
said filter stage including
a frequency selective filter; and
a second frequency selective filter connected to produce a substantially flat gain signal response over a pre-determined bandwidth.

2. The switching amplifier of claim 1, the switching amplifier including
a loop filter for receiving an input filter and generating the signal input to the power switching stage.

3. The switching amplifier of claim 2, the loop filter comprising an nth order filter, where ‘n’ is an integer value greater than one.

4. The switching amplifier of claim 1, the switching amplifier including
a feedback loop connecting the output of the filter stage to the input of the switching amplifier.

5. The switching amplifier of claim 1, each of the low pass and high pass filters having a common input;
the outputs of the low pass and high pass filters being connected to combine low pass and high pass filtered signals.

6. A PWM system comprising:
a pulse-width signal generating circuit for receiving an input signal and generating a pulse-width modulated signal; and
a filter circuit, said filter circuit comprising
a low pass filter; and
a high pass filter connected to produce a substantially flat signal response over a pre-determined bandwidth.

7. The PWM system of claim 6, each of the low pass and high pass filters having a common input;
the outputs of the low pass and high pass filters being connected to combine low pass and high pass filtered signals.

8. A pulse-width modulated amplifier comprising:
an n^{th} order loop filter, n having a value greater than one; the loop filter producing a stable loop output signal Ew from an input signal Ei;
a comparator for receiving loop output signal Ew and generating a pulse-width modulated signal Ep; and
a filter circuit for receiving the pulse-width modulated signal Ep and generating a smoothed signal, said filter circuit comprising
a low pass filter; and
a high pass filter connected to produce a substantially flat signal response over a pre-determined bandwidth.

9. A pulse-width modulated amplifier as in claim 9, the nth order loop filter including
an nth order integrator.
